(19) United States
(12) Patent Application Publication
(10) Pub. No.: US 2012/0019270 A1
(43) Pub. Date: Jan. 26, 2012

(54) Microfabricated pipette and method of manufacture

(76) Inventors: Dario G. Amodei, Princeton, NJ (US); Eve R. Schneider, Rosemont, NJ (US); Frederick S. Soo, Princeton, NJ (US)

(21) Appl. No.: 12/804,442

(22) Filed: Jul. 21, 2010

(51) Int. Cl. G01R 27/08; B01L 3/02; H01R 43/00; B32B 38/00

(52) U.S. Cl. 324/692; 156/278; 73/864.01; 29/825

(57) ABSTRACT

A pipette suitable for carrying out patch clamp techniques for characterizing the physiology of living cells is constructed using microfabrication techniques applied to silicon wafers. The pipette includes a body portion configured for mounting in a micromanipulator and a patch tip having a patch aperture. An internal passage through the pipette permits controlled dialysis of the cell contents. A solid conductive electrode near the patch tip can be connected to suitable electronics, permitting electrical activity of the cell to be monitored with very low access resistance and lowering the capacitance of the pipette. Other microfluidic devices such as pumps and valves are integrated into the device so that the dialysis can be rapidly controlled by electronic means. The pipette can also be configured so that multiple cells can be patched simultaneously, or multiple patches can be made on a single cell simultaneously. The design includes a method for separately fabricating the tip and body of the pipette, reducing the expense of fabrication.

### STATEMENT OF RIGHTS TO INVENTIONS MADE UNDER

### Federally Sponsored Research

This invention was made with government support under Grants No. R01 EY017934 and No. RO1 EY014196 awarded by the National Institutes of Health. The government has certain rights in this invention.

### BACKGROUND OF THE INVENTION

1. Field of the Invention

The present invention relates to a pipette, and more particularly, to a microfabricated pipette suitable for attachment to a living cell using the patch-clamp technique and a method for fabricating such a pipette.

2. Description of Related Art

Since its invention in the late 1970s, the patch clamp technique has revolutionized neurophysiology. As originally developed, this technique employs a glass micropipette to make a fluidic and/or electrical contact with the contents of a functioning cell. The micropipettes are formed by heating a glass capillary tube to its softening point and then drawing the tube while maintaining the continuity of its internal passage. The resulting pipette has a circular tip having an internal diameter typically of 1 to 3 μm that extends from a relatively large body that can be mounted in a micromanipulator.

The conventional patch clamp technique is shown schematically in FIGS. 1A-B. Using a microscope 2 for visualization, an operator carefully manipulates a micropipette 4 to bring its tip 6 into contact with the surface membrane of a cell 8 generally carried in an aqueous suspension in bath 10. It will be appreciated that for clarity of illustration, the micropipette and cells in FIG. 1B are shown far larger than their actual size and ion channels 12 are indicated schematically.

For reasons that are not completely understood, cell surfaces tend to be somewhat sticky, permitting an individual cell to become attached to the micropipette tip. The surface area of the cell in contact with the pipette is termed the “patch” area.

In order to effect the clamping, the operator must be able to visualize the cell of interest 8 and the micropipette tip 6 simultaneously through microscope 2. Thus, it is essential for the pipette to be thin and elongated in at least the tip portion, so the operator's view is not obstructed. Ordinarily, micropipette 4 is mounted in a micromanipulator (not shown) via its relatively large back end to facilitate precisely controllable adjustments of the tip position.

One conventional use of the foregoing system is to carry out whole-cell recording, also known as whole-cell patch clamping. For this application, pipette 4 typically is first purged of any debris by applying a slight positive pressure through its internal channel. Then, a slight negative pressure (i.e., a slight suction) may be applied just before cell contact is made, thereby urging the cell to become attached. With the proper technique, good quality seals can be made between the pipette and a cell in which the patch area and the rim and immediate inside surface pipette tip form a tight mechanical junction. The junction is sufficiently well sealed that neither fluids nor ions can pass from the interior of the pipette to the exterior bath, resulting in high electrical resistance across the junction. After the seal is made, the membrane may be breached, allowing dialysis of the cell, i.e. equilibration between the fluid contents of the cell and the pipette.

In another variant, the membrane is not ruptured, and the technique is then termed “cell attached patch clamping.” In still another operational mode, a pore-forming substance is introduced, resulting in a “perforated patch clamp,” or the patch may be removed from the cell, resulting in a so-called “inside out” or “outside out” patch clamp, depending on which surface is ultimately exposed to the extracellular solution. Although the description herein is given with primary reference to the whole cell patch-clamp method, the devices and principles apply generally to these and other patch clamp techniques.

The conventional patch clamp technique can be used to collect a range of scientific data pertaining to the microphysiology of individual living cells. A particularly valuable use is to monitor the electrical activity of an individual cell, which may be accomplished using the whole-cell or perforated patch clamp variations. Alternatively, the electrical activity of individual ion channels within the patch can be sensed using the inside-out or cell attached methods.

It is now recognized that widely divergent functions of living organisms are mediated by minute electrical currents flowing through the surface of cells. Ordinarily, these currents are transmitted by ion channels at the cell surface membrane. Electrical measurements using the patch-clamp technique rely on a conduction path that connects the cell's cytoplasm to suitable electronics, e.g. permitting current flows or potential differences between the cytoplasm and a ground reference (usually the bath in which the cell is immersed) to be sensed. Typically, the pipette contains a conductive aqueous solution containing salts and other compounds that provides immediate fluidic and electrical contact with the cytoplasm. A metal wire also in contact with the liquid is then used to complete the connection with the electronics.

In order to minimize the effective lead impedance and improve the electrical connection, the wire, which inherently has much higher conductivity than typical ionic liquids, is inserted at least part way into the pipette, to shorten the liquid part of the conduction path. However, the narrowing of the tip end both decreases the conductance of the end portion of the conductive path markedly and impedes the insertion of the wire toward the tip end in a drawn glass pipette, limiting the degree to which the total resistance of the path can be reduced.

Exemplary cellular functions that have been examined using the patch clamp technique to make electrical measurements include the conversion of light into electrical signals in the retina, the communication of electrical impulses from the brain through neurons connected to muscles to make them move, screening of pharmaceutical compounds for adverse effects on pacemaker cells in the heart, and measuring the electrical activity of cells within the brain to study memory, cognition, and other neural functions.

Referring still to FIGS. 1A-B, a configuration is shown for the conventional use of the patch clamp for these electrical measurements. Micropipette 4 includes an electrode inserted into the bore of the pipette. This conductor is ultimately connected to an input of patch clamp amplifier 14, which is referenced to the potential of bath 10. The electrode is thus electrically connected and able to monitor the cell cytoplasm via the liquid path from the conductor in the bore of the pipette, through the body of the pipette, and through the tip 6, permitting the minute electrical currents propagated by ion channels 12 on the cell surface to be recorded.

The minute currents involved and the relatively high source impedance of the electrical path from the amplifier into the cell (i.e. ‘input resistance’) present a significant impediment to obtaining reliable electrical measurements in the face of inevitable electrical noise. The seal itself must provide electrical resistance that is much larger than the input resistance, and also much larger than the electrical resistance of the cell's ion channels.

Thus, the quality of a patch seal is generally characterized by the electrical resistance between the electrode (and the fluid within the pipette) and the aqueous carrier bath in which the pipette and cell are immersed. A good seal is conventionally denoted as a “gigaseal,” meaning that the foregoing resistance is of the order of a gigaohm or more. A number of requirements are known to promote the reliable formation of gigaseals, notably including the dimensions at the pipette tip and its smoothness at the nanometer scale.

Despite the advances that have come from the patch clamp technique, the glass micropipettes conventionally used have inherent characteristics that limit the technique's applicability and the research data that it can produce. Many of these limitations directly arise from mechanical and practical attributes of conventional pipettes. The production of micropipettes by drawing capillary tubes is notoriously difficult and time-consuming. The pipette must be manually filled using a fine gauge needle which must be kept free of dust and other contaminants. The filled pipette must be manually mounted on the micromanipulator, usually requiring first threading the metal electrode wire into the bore of the pipette and then inserting the pipette into the holder and securing it. These steps require significant manual dexterity and are prone to error, as the wire is fragile and can be bent or contaminated by oils or other residues. After being used, a pipette is contaminated and must be dismounted and discarded, since its tiny size and fragility inhibit effective cleaning. The individual manufacture required and low yield of the drawing process present further serious complications. In addition, the reproducibility of tip geometry from pipette to pipette is relatively poor.

In addition to problems in manufacture, conventional pipettes have several severe functional limitations. Because the pipette is basically an open tube without any internal structure, upon rupturing the cell membrane the contents of the cell are quickly and irreversibly mixed with the contents of the pipette. The resulting dilution, which can be many thousand-fold because the pipette internal volume is many times that of the cell, disrupts many of the important biochemical reactions necessary for the normal functioning of the cell. This adds uncertainty to the measurement, and in some cases makes the desired measurement impossible. The dilution also eventually kills the cell, limiting the time over which measurements can be taken. Although several techniques have been developed to mitigate these problems, these techniques add much difficulty and complexity to the process, have their own inherent problems, and as a result are only rarely practiced.

One of the primary commercial applications of the patch pipette is in pharmaceutical discovery and testing, as Federal mandates require that compounds be tested for interference with ion channels in the heart (hERG channels). In addition to the manufacturing and functional problems listed above, traditional patch clamp is also both expensive and time-consuming, as it requires a microscope, micro-manipulators, and highly trained personnel to assemble, operate and maintain the apparatus, including pulling individual pipettes and adjusting the pipette puller to compensate for changes in humidity, temperature and normal wear and tear. Because of the manual dexterity needed to manufacture, fill, mount and maneuver pipettes, these steps cannot be easily automated, limiting the overall productivity of a patch clamp apparatus and the scalability of the method.

A variant of the patch clamp technique, often termed the planar patch method, partially addresses some of these difficulties. This approach employs larger recording structures in which a planar surface is provided with multiple apertures, permitting multiple cells to be studied simultaneously without requiring a microscope or micromanipulators. However, such structures are not controllable, in that particular cells cannot be identified and selectively clamped. Instead, the technique relies on the random attachment of multiple cells in a bath, limiting a researcher's ability to control the data collection. In addition, many embodiments of this technique do not form gigaseals reliably or at all, reducing the quality of the recording and limiting its usefulness for government approval. Another major problem is the planar patch clamp technique is limited to studying individual cells that are dissociated in a carrier liquid and removed from their original anatomical position and function. However, many if not most physiological functions in living beings rely on the collective operation of cellular-level electrical and chemical mechanisms. Such information inherently cannot be obtained by studying isolated cells.

Thus, there remains a need for a pipette that can be readily, reliably, and inexpensively fabricated with different internal structures and a broader range of tip configurations than can be obtained either with drawn capillary glass pipette or planar patch arrays. There is also a need for a pipette where the internal dialysis of the cell can be easily controlled without incurring the difficulty or cost of existing dialysis techniques. Finally, there is a need for a pipette that can record from many cells simultaneously, in cell culture or intact tissue, with the same accuracy and resolution as traditional methods, while requiring less time, expense and technical expertise than traditional methods.

### SUMMARY OF THE INVENTION

The present invention is directed in one aspect to a microfabricated pipette useful for making patch-clamp connections and measurements of living cells. Further provided is a method for constructing such a microfabricated pipette.

In an embodiment, the microfabricated pipette comprises a body section and a tip section extending from the body section. A through internal passage extends from a back aperture proximate a back end of the body section to a patch aperture proximate a patch end of the pipette tip. The internal passage includes an internal cavity in the body section in fluidic communication with an internal tip channel terminating at the patch aperture. The pipette is configured and dimensioned to form a patch clamp seal with a cell at the patch aperture. The internal passage permits perfusion of a desired fluid carried in the passage into the cell itself.

In preferred embodiments, the microfabricated pipette further includes at least one electrode proximate the patch aperture that is connected to a conductor leading through the internal passage. The conductor is adapted to be connected to electronics for detecting currents generated by the cell. Preferably, the electrode system provides low source resistance, low capacitance, and a low time constant, permitting accurate measurements of transient signals in the face of ambient electric noise. In some preferred embodiments the internal geometry of the passage is a simple U-shaped channel. In other embodiments the internal geometry of the passage may also include several branches or junctions so that different reagents can be flowed into the tip of the pipette. These branches may also be very narrow or long to prevent diffusion of substances from the cell or increase electrical resistance between different parts of the pipette.

Alternate embodiments may also include a plurality of patch apertures connected to a plurality of internal channels, so that many cells can be patched simultaneously.

Alternate embodiments may also include pumps and valves within the channels to control the flow of fluid through the channels as well as the electrical connectivity among different branches.

There is further provided a method for microfabricating a pipette having top, bottom, and side walls and a pipette tip, and a through internal passage extending from a back aperture proximate a back end through an internal tip channel to a patch aperture in a patch end of the pipette tip. The method comprises the steps of: (i) providing a base wafer having a top surface and a bottom surface and ceiling wafer having a top surface and a bottom surface; (ii) removing material from a portion of the top surface of the base wafer to form therein the internal passage comprising an internal cavity in fluidic communication with an internal tip channel; (iii) coating the bottom surface of the ceiling wafer with an insulating layer and the top surface of the base wafer with an insulating layer; (iv) bonding the bottom surface of the ceiling wafer to the top surface of the base wafer to enclose the internal passage; (v) thinning the ceiling wafer by removing material from substantially all of the top surface without removing the insulating layer of the ceiling wafer; (vi) defining side walls of the pipette by removing material of the base wafer and the ceiling wafer surrounding the internal tip channel; and (vii) releasing the pipette tip by removing material of the base wafer and the ceiling wafer surrounding the internal tip channel. Thus constructed, the pipette is configured and dimensioned to form a patch clamp seal with a cell at the patch aperture. Because the internal channels are photolithographically defined, the number and geometry of the internal channels as well as the external apertures can be easily varied through a change in one or more of photomasks used.

### BRIEF DESCRIPTION OF THE DRAWINGS

The invention will be more fully understood and further advantages will become apparent when reference is had to the following detailed description of the preferred embodiments of the invention and the accompanying drawings, wherein like reference numeral denote similar elements throughout the several views and in which:

FIGS. 1A and 1B show schematically the conventional patch clamp technique; FIG. 1B shows an enlarged view of the region of FIG. 1A in which contact is made between a micropipette and a cell being studied;

FIG. 2A depicts a side elevation view of a microfabricated pipette of the invention;

FIG. 2B is a top cross-sectional view of the microfabricated pipette of FIG. 2A, taken at II;

FIGS. 3A and 3B respectively depict side and top views of another microfabricated pipette of the invention, and FIG. 3C provides an enlarged view of a portion of FIG. 3B in the tip and neck region of the microfabricated pipette;

FIG. 4 depicts in plan view an alternate placement of the aperture of the microfabricated pipette of FIG. 3;

FIGS. 5-11 depict in plan view different forms of the internal manifold structure of the present microfabricated pipette;

FIG. 12 depicts in plan view an electro-osmotic pump included in the internal channel of some embodiments of the present microfabricated pipette;

FIG. 13 depicts in end perspective view a sequence of stages A-E in the microfabrication of a microfabricated pipette of the invention; and

FIGS. 14A-14H depict an implementation of the method of the present invention, FIGS. 14A, 14C, 14E, and 14H depicting various states in the fabrication of a microfabricated pipette in plan view, while FIGS. 14B, 14D, 14F, and 14G depicting the operations in steps 1-4 of the implementation of this method.

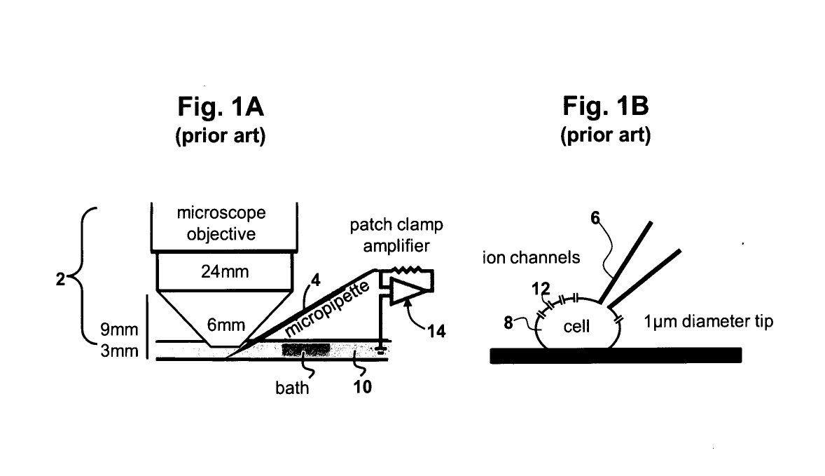

### DESCRIPTION OF THE PREFERRED EMBODIMENTS

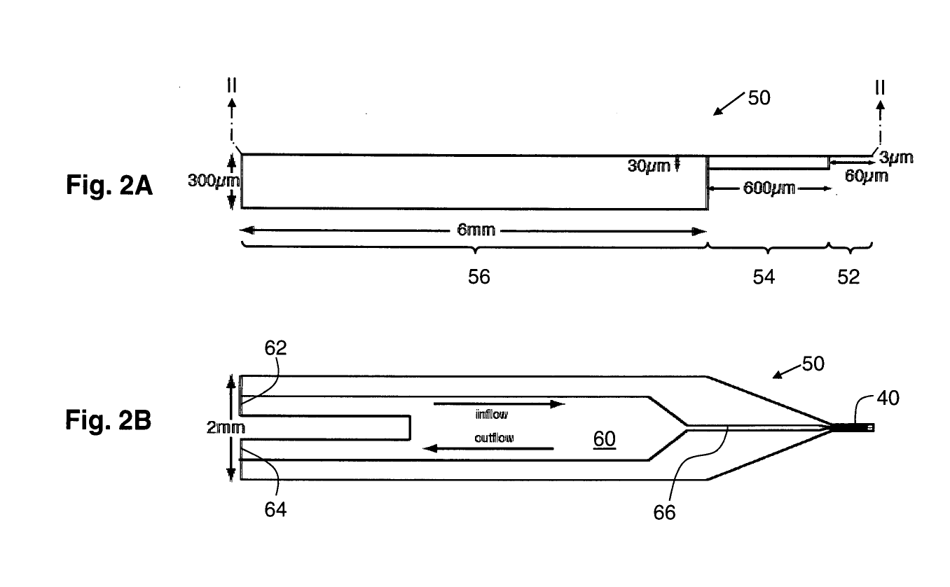

FIGS. 2A-2B depict a microfabricated pipette 50 in accordance with an aspect of the invention. Microfabricated pipette 50 includes tip portion 52, neck portion 54, and body portion 56. For clarity of illustration of the internal structure of microfabricated pipette 50, including pipette internal cavity 60, FIG. 2B is depicted in top cross-sectional view. The various dimensions shown in the drawings included herewith, including FIGS. 2A and 2B, are representative of preferred embodiments, but may be adjusted to accommodate particular applications. Cavity 60 includes inlet port 62 and outlet port 64, through which fluid may be introduced and extracted. Cavity 60 is generally U-shaped, and fluidically communicates at its bottom with pipette end 40 through neck channel 66. Thus, an external fluid may be introduced and dialyzed with a cell patch-clamped using microfabricated pipette 50.

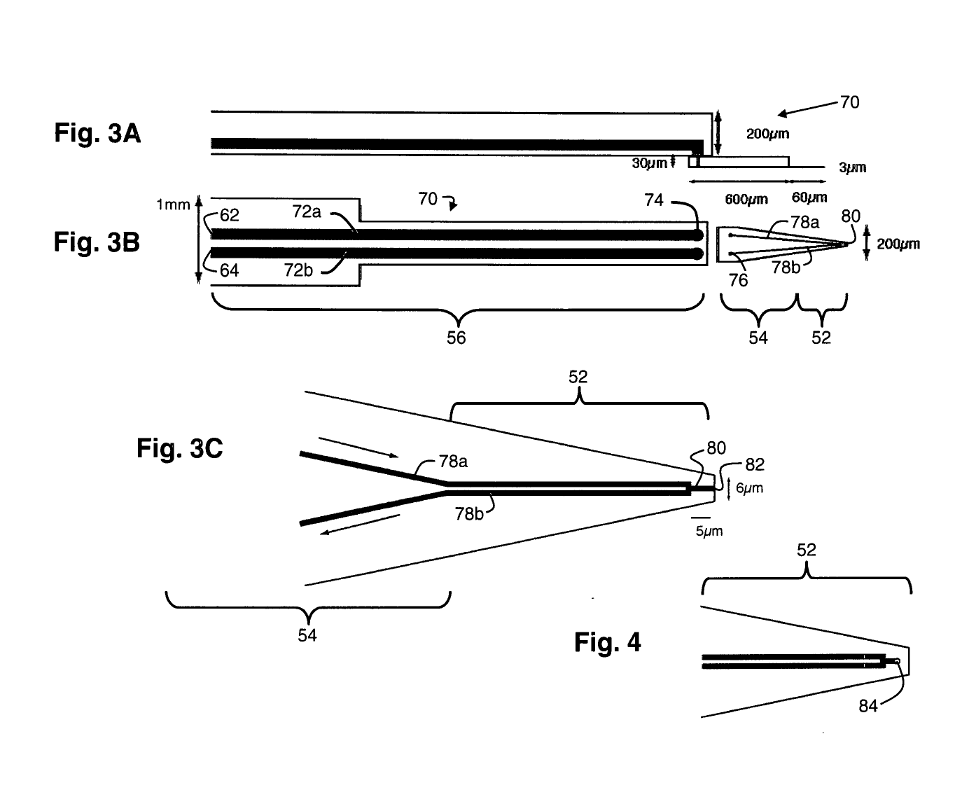

An alternative construction of a microfabricated pipette 70 having functionality similar to that of microfabricated pipette 50 of FIG. 2 is shown in FIGS. 3A-C. Here, the tip and neck portions 52, 54 and the body portion 56 are formed as two separate workpieces that are later joined by adhesive bonding, thermal fusion, or other suitable method. This embodiment recognizes the different size scales required for the general features of the respective parts of the microfabricated pipette, and fabrication methods suited for each. Body portion 56 includes inflow channel 72a and outflow channel 72b, each extending along the elongated direction of portion 56 and terminating in an aperture, e.g. apertures 74 in a lower side of portion 56. In a preferred embodiment, the channels in the body portion may be about 300 μm wide and 200 μm deep, with the external dimensions permitting the body portion to be secured in a micromanipulator. The body portion 56 may be constructed of silicon, using microelectromechanical systems (MEMS) fabrication techniques. The basic techniques used in MEMS include deposition of material layers of different compositions, photolithograpic patterning of these layers, and etching to produce the requisite shapes. Alternatively, plastics, polymers, or other materials may be used and machined to provide the required internal and external structure.

The neck 52 and tip 54 portions are much smaller, typically a fraction of a millimeter in size, so that microfabrication in silicon is preferred, because it permits simultaneous formation of large numbers of devices in which the dimensions and intricate geometric features are accurately reproducible. Microfabrication permits complicated structures to be attained, whereas the conventional process of drawing glass capillary tubes is far more limited, generally to a single through channel. Although multi-barreled tubing is available, it is rarely if ever used in forming pipettes. Otherwise highly desired experiments inherently cannot be carried out with this simple structure. In addition, microfabrication also accommodates integral formation of certain internal structures, e.g. pumps, valves, and conductive wires, which further enhance the functionality of the microfabricated pipette for certain experiments. Although microfabrication requires expensive and highly specialized facilities, it advantageously is a batch process in which a large number of devices can be formed simultaneously on a silicon wafer at fixed cost per wafer, and with highly reproducible dimensions and intricate configurations not possible with previous methods. Separate production of the tip and body allows the tip to be smaller, so that many tips can be formed on a single silicon wafer, significantly lowering the cost per tip.

Referring still to FIG. 3B, apertures, e.g. 76, configured to mate with apertures 74 in the body portion, are formed in the top side of the tip and neck portion 52, 54. These apertures 76 lead to inflow channel 78a and outflow channel 78b. These latter channels join to form an outlet 80 that terminates in a patch aperture 82. Thus, fluids may be introduced and withdrawn from both channels in a manner similar to that possible with the FIG. 2 microfabricated pipette. A further variant of the FIG. 3 microfabricated pipette is shown in FIG. 4, wherein the patch aperture 84 is located on the bottom side of the tip, instead of at the end of the tip at 82. Of course, aperture 84 could also be located on the top surface of the tip. Although the structures in FIGS. 2-4 are shown with two channels (an inlet and an outlet), microfabricated pipettes alternatively may be constructed with either a single channel or with a multiplicity of channels. In addition, a microfabricated pipette may be fabricated with multiple patch tips and apertures. The outflow channel may be used in some patch-clamp applications as a reservoir for collecting cell products generated during the measurement process.

A microfabricated pipette having the configuration shown in FIG. 2, 3, or 4 is readily employed in forming a patch-clamp seal with a cell of interest, using techniques such as those described above. However, a wider range of structures is attainable with the present microfabricated pipette, so that a broader range of experiments heretofore impossible with a conventional, single-bore glass capillary microfabricated pipette can now be carried out.

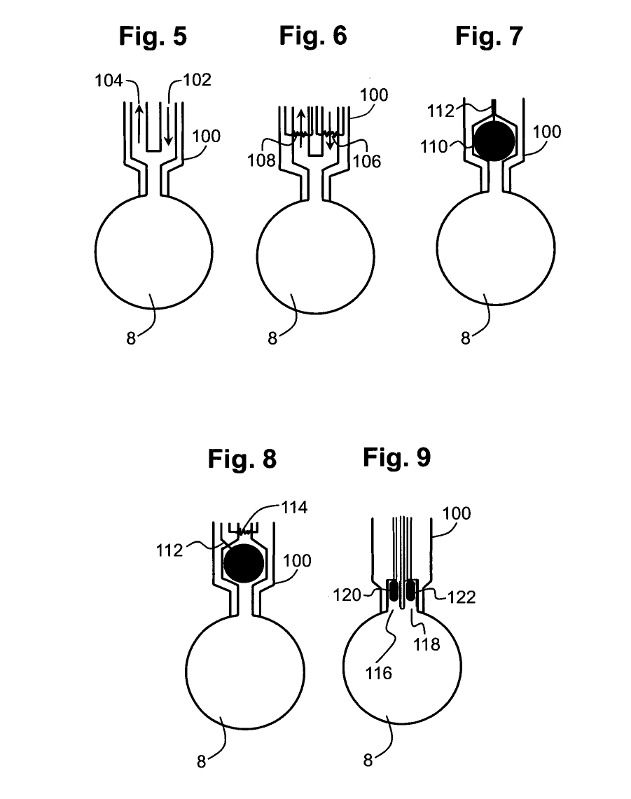

Still other forms of the internal structure of the microfabricated pipette are depicted by FIGS. 5-11, each of which shows a cell 8 patch-clamped to the tip of a microfabricated pipette 100. The microfabricated pipettes of FIGS. 5-6 both include inlet 102 and outlet 104 channels that join only a small distance from the patch aperture. Typically the distance is about 5 μm, but longer or shorter lengths are also permissible. By minimizing the distance between the junction of the two channels and the cell, diffusion times are minimized, permitting more rapid dialysis than is possible with a conventional drawn capillary glass microfabricated pipette. It is believed that too short a distance inhibits formation of a high-quality gigaseal, by not permitting a small area of the cell surface (often called a “bleb”) to enter the patch aperture and seal with the interior walls of the aperture. The microfabricated pipette of FIG. 6 includes resistive elements 106 and 108 located in the respective inlet and outlet channels. Energizing either element by passing an electric current from a suitable source (not shown), results in local heating, thereby causing formation of a local bubble that is believed to act as a valve in that channel by impeding flow, inhibiting diffusion, and/or increasing electrical resistance. Alternatively, a similar valving action may be provided by a thermally sensitive polymer that swells when heated. Use of these valves permits a suitable fluid to be controllably injected through the inlet channel, and be dialyzed rapidly.

The patch-clamp technique is most commonly applied in studies that entail monitoring of electrical activity of cells. However, the present microfabricated pipette also finds uses that do not involve electrical measurements. For example, the pipette may be used to extract genetic material to be studied by other external means. Alternatively, the pipette may be used to inject material (e.g., a drug) into a patched cell, with the effect sensed by other means, e.g. optical measurements, fluorescence, or other non-electronic readout, or by sensing effects in other nearby cells in intact tissue that act in concert with the patched cell. Embodiments of the pipette used in these and other applications need not have internal electrodes or other electrical measurement means.

The microfabricated pipettes of FIGS. 7-8 both include an electrode in the form of a conductive pad 110 located close to the patch aperture. The electrode is connected to a conductor 112 routed through the microfabricated pipette channel, permitting monitoring of electrical activity in very close proximity to the cell itself. Conductor 112 is preferably a metal trace deposited in the internal channel, but could also consist of polysilicon or another conductive material. The internal channel immediately adjacent to the conductive pad may be narrowed to the minimum cross section that can be reliably fabricated, but be kept wide enough so that fluid can be flowed through the channel during approach to the cell to keep the patch aperture free of debris. The possible cross-sectional dimensions thus depend upon the length of the channel and the amount of pressure that can be applied to maintain fluid flow. As small a cross section as possible is preferred, to reduce the rate of dilution of the cell by dialysis, the final dilution of the cell, and also the effective capacitance of the pipette. The microfabricated pipette of FIG. 8 also includes a valve 114 similar to those shown in FIG. 6, which offers another method of diffusion restriction.

FIG. 9 shows a microfabricated pipette configuration in which there are two patch apertures 116, 118 in close proximity, with respective electrodes 120, 122. Each patch aperture is in communication with a separate internal cavity in the body section which terminates in its own back aperture, thus providing fluidic and electrical isolation between the separate channels. The FIG. 9 configuration is beneficially employed in making higher precision and quality electrical measurements, because the separate electrodes can be used for injecting current and monitoring potential, whereby the deleterious effect of error due to current flowing through the measurement path is eliminated, increasing measurement accuracy and reducing noise. This approach is conventionally termed a four point measurement. Moreover, the electrodes in this configuration can be made much smaller, further reducing the capacitance of the pipette and reducing its overall size.

It is preferred that the conductive pads used in the present microfabricated pipette be provided with a suitable coating to reduce the series impedance of the interface between the electrode and the tip solution. The coating preferably comprises electrodeposited platinum black. Other useful coating materials include titanium nitride and carbon nanotubes. Titanium nitride is often applied by vapor deposition, while carbon nanotubes may be formed by the decomposition of a carbon-containing gas such as ethylene in the presence of a catalyst such as Ni metal. Of course, other formation methods for any of these coating substances may be used. Suitable coating materials all decrease the impedance of the pad-fluid interface, with platinum black and titanium nitride providing low DC and AC resistance, while carbon nanotubes provide very low AC resistance. A conductor is connected at one end to the conductive pad, and the other end is routed through the internal channel of the microfabricated pipette, so that it can be connected, usually though additional cabling, to the input of the patch clamp amplifier. Although a discrete thin wire conductor may be used, a deposited conductive trace is preferred. The conductive trace preferably consists essentially of at least one metal selected from the group consisting of W, Ti, Ir, or alloys thereof. Any other metal providing sufficient conductivity and a sufficiently high melting point may be used. For embodiments in which fusion bonding is used to join the base and ceiling portions of the pipette, a melting point above 900° C. is preferred. The same metals may also be used as base material (i.e. the substrate on which coating is applied) for the conductive pads.

Both low resistance and low capacitance are desired, so that that the effective time constant τ=R.C (R=effective input resistance, C=effective capacitance of the pipette for the measurement is short enough to permit the capture of transient cell currents without distortion of the intrinsic waveform. Also the capacitance must be small enough so that the noise arising from the capacitance does not overwhelm the recording. Typically the pipette capacitance must be smaller than the typical cell capacitance (30 pF). For recordings from single channels, the pipette capacitance must also be lower than the capacitance of the input stages of the amplifier (1-10 pF). The time constant can be measured by the decay in current following a brief voltage pulse. Preferably, the electrode system of the present microfabricated pipette has low input impedance and low noise as a result of both low series resistance and low pipette capacitance.

Preferably, the capacitance as measured between the interior fluid of the pipette and the exterior bath (e.g. the capacitance through the wall of the pipette) is at most about 30 pF, and the electrical series resistance from the back aperture to the tip aperture is at most 100 MΩ, and more preferably, at most about 2 MΩ. The resulting time constant τ=R.C is less than about 3 ms when the electrical resistance is at most 100 MΩ, and less than about 0.07 ms when the electrical resistance is at most 2 MΩ.

The use of a deposited conductive trace instead of a discrete wire also decouples the fluidic and electrical connections between the pipette and the cell contents. As noted above, the same cross-section in the tip of prior art pipettes must serve both as a fluidic coupling and as an electrical coupling (e.g. via ionic conductivity through the fluid) to minimize lead resistance. In this region of the tip, the electrical resistance through the fluid, and the fluidic resistance to diffusion are proportional. However, in some cases it is valuable for the electrical resistance to be low, but the resistance to diffusion (e.g. dialysis) to be high, which can be accommodated with a small, integrated trace and pad. By incorporating the conductor directly into the pipette structure, the geometry of the fluid path (i.e. its length, cross section and branching) can be varied without strongly affecting the electrical coupling into the cell. If needed, electro-osmotic pumps and/or valve elements can provide independent control of the fluid path and dialysis.

The patch aperture in the preferred embodiment is approximately square, but other shapes, including circular are also possible for the present microfabricated pipette. It is understood that the term “diameter” in reference to a patch aperture that is non-circular refers to any lateral dimension, such as the side or diagonal measurement of a square aperture. The present microfabricated pipette preferably has a diameter ranging from about 0.1 μm to about 5 μm, depending on the nature and configuration of the cell to be patched and the measurements to be carried out. A diameter of 5 μm may be used for “loose patching” of cells, in which the pipette only gently contacts the surface of the cell, while 0.1 μm may be useful, e.g. for patching particular regions of cells having small feature size, such as neural dendrites. More preferably, the diameter ranges from about 1.0 μm to about 1.6 μm, which is believed to be a favorable diameter range for seal formation in the majority of patch clamp applications. The interior channel of the microfabricated pipette in some preferred embodiments has larger cross sectional dimensions, which may thus range from about from 1×1 μm to 200×200 μm. Small cross-sectional areas are useful for achieving low capacitance and low rates of dialysis, while large cross-sectional areas lower the input electrical resistance in embodiments that do not incorporate an integrated electrode, reduce the risk of clogging by debris, and allow fluids to flow more quickly in embodiments wherein fluid is driven by external pressure.

Some embodiments of the present microfabricated pipette include an electro-osmotic pump, such as that depicted generally at 130 in FIG. 12, disposed in the internal passage. Applying a voltage across electrodes 136a and 136b, respectively located in fluid inlet 132 and fluid outlet 134 creates an electric field that in turn results in generation of a pressure differential. Pump 130 preferably includes a plurality of vanes 138. The electrodes 136a and 136b are constructed by metal deposition and coating similar to that used in FIGS. 7-9, and are attached to wires which lead out to the back of the pipette where they connect to external electronics. The vanes 138 are constructed via photolithography and etching similar to that used for the main internal channel of the pipette. The vanes preferably extend substantially all the way from the floor to the roof, as any large unconstricted area through which fluid can pass will decrease the efficacy of the pump. The length and number of vanes will depend upon the length and size of the internal channel and the speed at which the fluid needs to flow for a particular application. In a representative embodiment, 10 vanes of thickness 1 μm and length of 100 μm each are used, but other configurations are also possible. It is preferred that the vane spacing be the minimum possible, consistent with the fabrication method used. The total surface area and volume of the pump preferably is sufficient to allow pumping pressures greater than 0.1 psi and linear velocities in excess of 100 μm/sec. In an alternate embodiment the vanes may be replaced by protrusions from the base of the channel which narrow the passage to 0.5 μm or less.

The pump is operated by applying a voltage difference to the wires, which causes a forward pressure to be applied to the fluid via the mechanism of electro-osmotic flow. This forward pressure drives fluid through the channel, facilitating the manipulation of fluids within the pipette. The vanes increase the fluid-insulator surface area (which drives electro-osmotic flow), thereby increasing the strength of the pump. In a preferred embodiment, pumps with opposed high-pressure forward and low-pressure reverse stages may preferably be used to reduce the electrophoretic separation of charges that occurs during pumping; multiple stages in series may be employed to reduce the voltage required for pumping and/or increase the pressure attained by the pumping system.

In an alternative embodiment, the full extension vertical vanes described above are replaced with a ramped design, in which the bottom of the chamber has a long bump which rises to within a short distance of the top of the chamber; the height of these bumps can be controlled precisely by using deposition techniques, so the space can be very narrow, e.g., as small as 100 nm. This speed bump can be made very long, so that the total surface area is large and also the volume that is pumped is large.

A more preferred embodiment uses a low-electrophoresis pump design in which a forward, high pressure stage with numerous vanes and therefore pressure is put in series with a low pressure reverse stage (with very few vanes and low pressure) so that the total electric field over the entire length of the pump is zero (so no electrophoresis), at the cost of some cancellation of pumping action due to the reverse stage. A multiplicity of these pumps is placed in series to achieve the desired pressure and flow while reducing the voltage required for each stage. Minimizing electrophoretic separation is especially desired for electrophysiological measurements, so that the differential migration of Ca²⁺ and Mg²⁺ versus Na⁺ and the opposite migration of negatively charged ions (e.g., Cl⁻) does not affect the measurement.

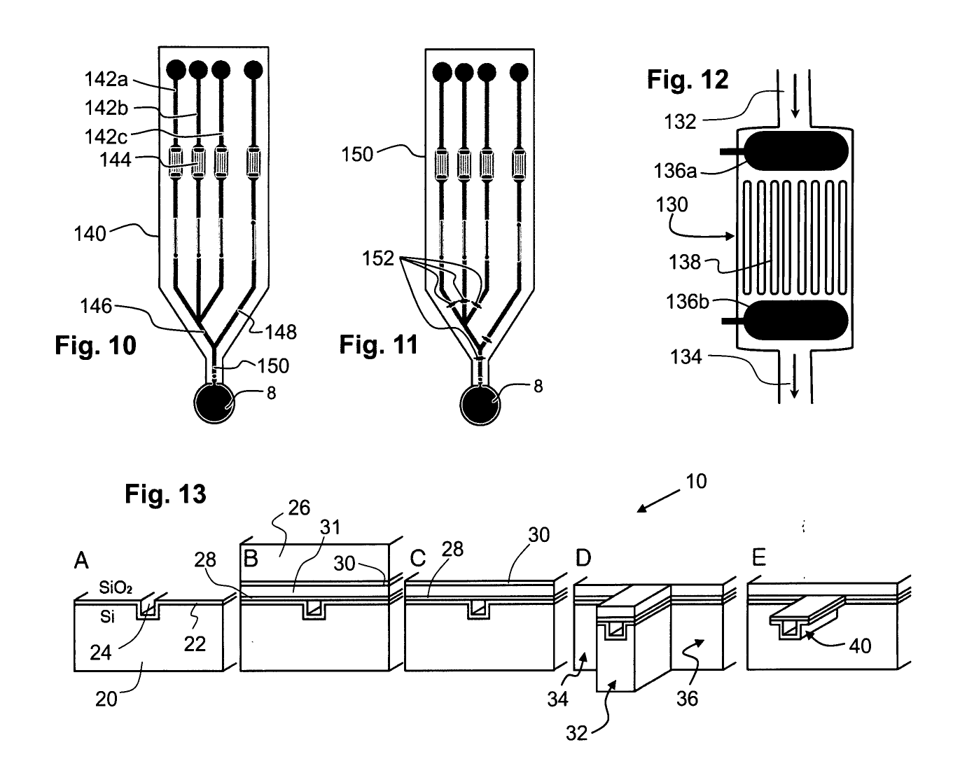

FIG. 10 depicts a microfabricated pipette configuration 140 having a manifold with multiple inlet channels 142a, 142b, 142c, each with an in-line electro-osmotic pump 144, that join to form a combined inlet 146 that in turn joins with an outlet channel 148, leading to outlet port 150. The patch clamp seal with cell 8 is made near the intersection of the combined inlet 146 and the outlet 148. Using multiple inlets permits a researcher to controllably dialyze the cell 8 with different substances being introduced. For example, such a technique is useful in testing the pharmacological activity of different substances, which can be individually dialyzed, and the electrical activity or other measure of cellular function monitored. The FIG. 11 configuration 150 reflects the further addition of thermal valves 152 in one or more of the branches, similar to those provided in FIG. 6, discussed above. The use of such valves provides more precise control of the cell dialysis.

Referring now to FIG. 13, there is shown generally at 10 a sequence of stages A-E of a microfabrication process particularly demonstrating the formation of the tip area in embodiments of the present microfabricated pipette. Preferably, the microfabrication process employs wafers that consist essentially of silicon. Such wafers include both those formed by slicing a larger single crystal of Si (which may be either high-purity, low-conductivity Si or less pure but more conductive forms) into thin layers, and wafers of type conventionally known as “silicon on insulator,” or “SOI” wafers. An SOI wafer typically is composed primarily of silicon, but with a buried oxide layer sandwiched between adjacent silicon layers. One of the outside layers of the SOI wafer may be employed for the fabrication of Si-based electronic integrated circuitry. Si wafers of either type may further include suitable insulative coatings on their surface, such as silicon oxide or nitride, and additional electrical structures formed by processes familiar in the construction of integrated circuits.

In step A of the method depicted by FIG. 13, an interior cavity terminating in channel 24 is formed in the top surface of a starting silicon wafer 20. Channel 24, which ultimately will become the microfabricated pipette tip, typically has a rectangular cross-section about 1 μm wide and 1 μm deep, but other shapes, including a tapered or flared end, may be used in some embodiments. The interior portion of the cavity away from the channel 24 end may narrow, widen and/or deepen and be given different shapes useful in various end-use applications.

Channel 24 may be produced in any suitable way, but is conveniently patterned photolithographically and etched to form the desired internal channel shape. Multiple photolithographic patterning and etching steps may be employed in order to achieve a channel that deepens further away from the tip. Thereafter, a surface layer 22 of SiO₂ is applied (e.g., by thermal deposition or oxidation) to the top surface, including through channel 24. In step B, a ceiling wafer 26 is thermally bonded to the top surface of wafer 20, thereby defining an internal cavity channel 24 as closed on all sides. The ceiling wafer 26 includes a lower bonding layer 28 of SiO₂, which provides electrical insulation for the roof of channel 24. In the embodiment shown, ceiling wafer 26 is an SOI wafer that also includes an intermediate buried layer 30 of SiO₂ and a Si device layer 31. Step C entails thinning ceiling wafer 26 down to intermediate layer 28, preferably by grinding and etching of intermediate layer 28. Alternatively, ceiling wafer 26 need not be an SOI wafer having intermediate layer 30, in which case the thinning is preferably done by grinding and polishing. The sides of the microfabricated pipette are defined in step D by removal of material from both base wafer 20 and ceiling wafer 26 to form end faces 32 and 34 of the microfabricated pipette body. Still more material is removed from base wafer 20 underneath and above channel 24 to form the extended tip 40 of the microfabricated pipette, as shown in step E.

The process shown schematically in FIG. 13 may further include additional steps to remove exterior material on the bottom and sides to form a reduced neck region, e.g. as shown for neck region 54 in the embodiment of FIGS. 2A-2B. The neck region is preferably at most 1 mm long, and more preferably at most 500 μm long.

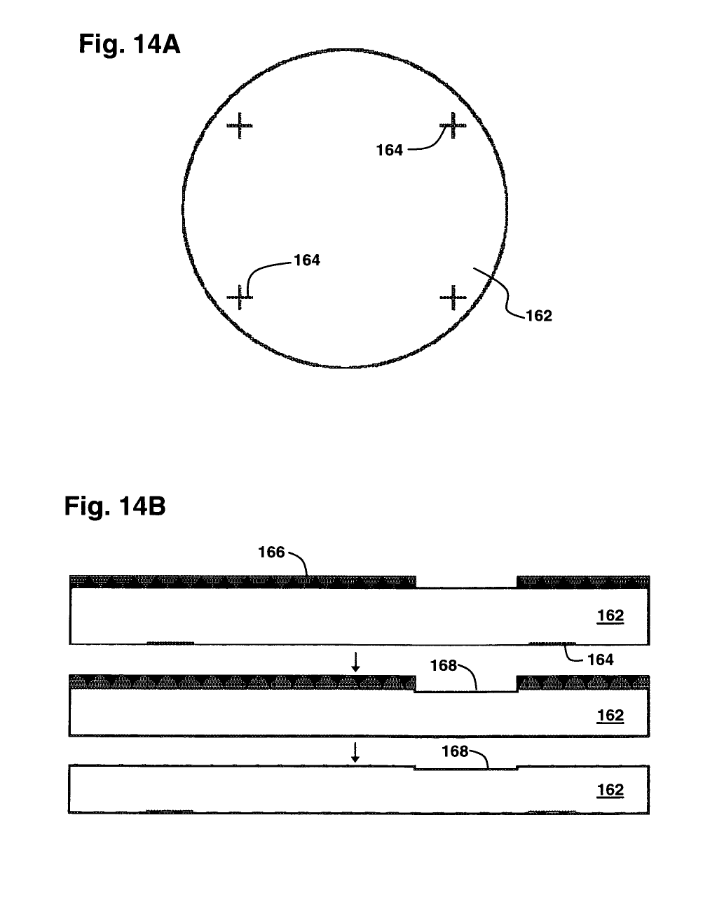

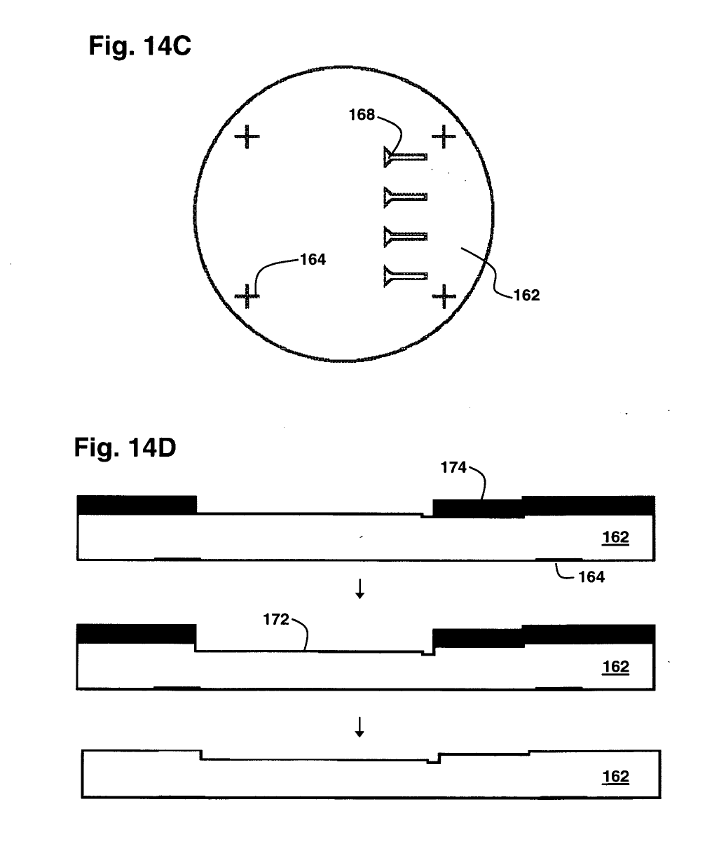

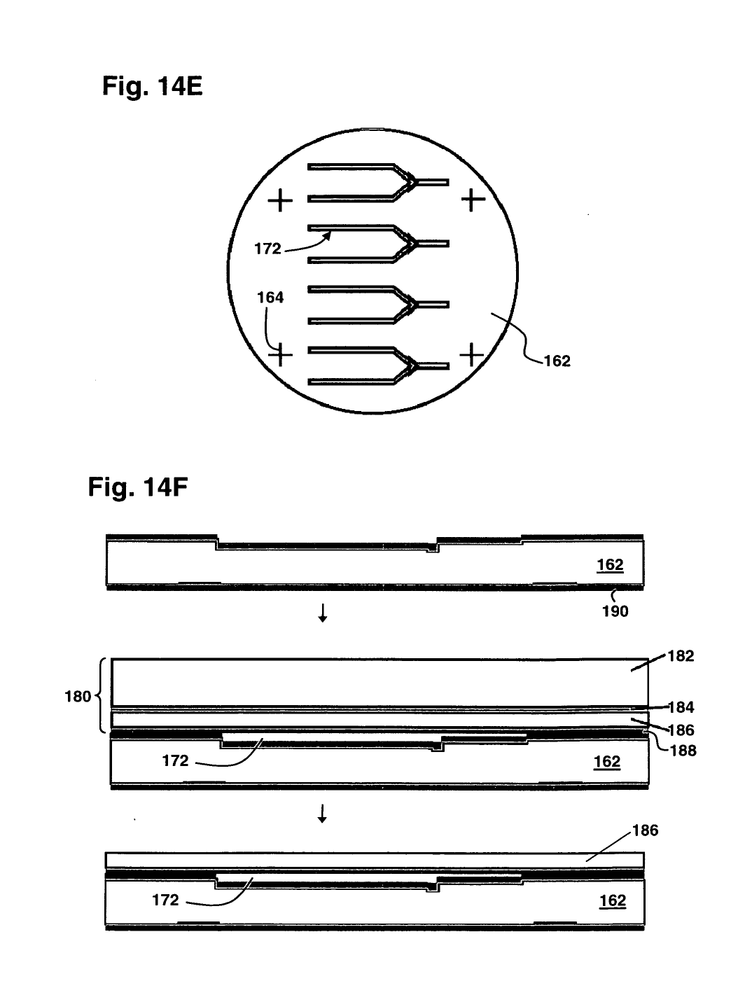

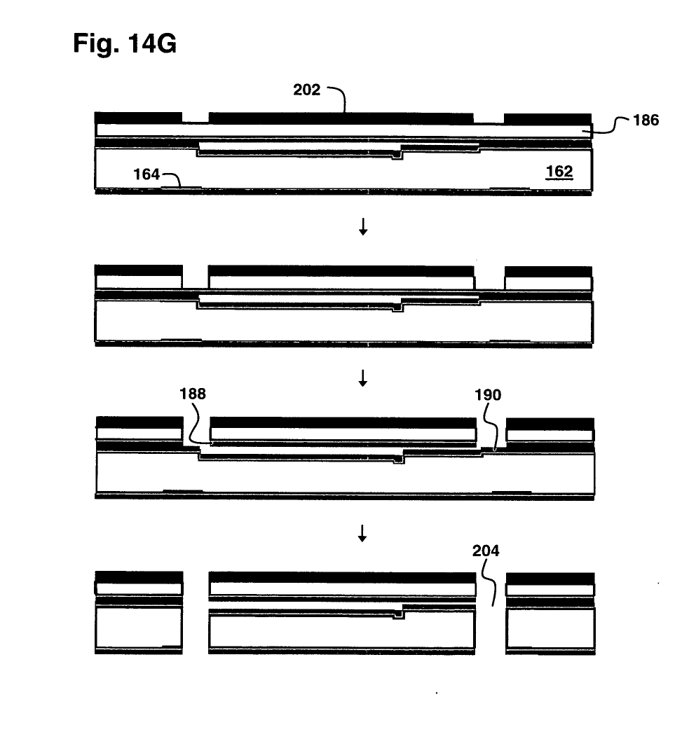

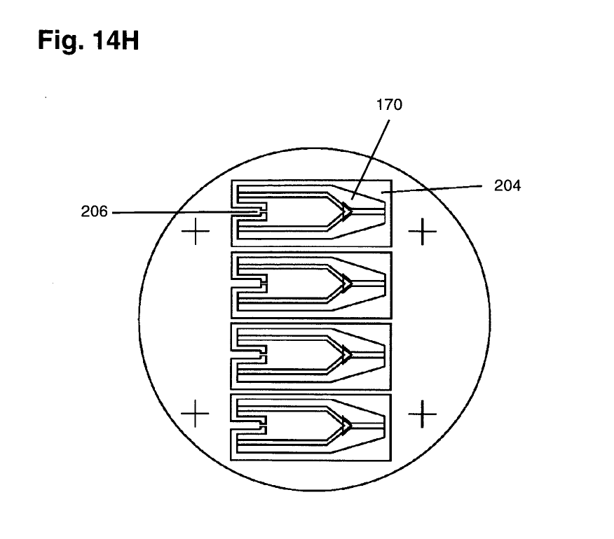

FIG. 14 provide additional detail of an implementation of a method of the invention by which various forms of the present microfabricated pipette may be formed using silicon microfabrication. For the sake of clarity, only a small number of microfabricated pipette devices are described in the following discussion and depicted in the accompanying figures, but it will be understood that a much larger number of microfabricated pipettes can be formed, limited only by the size of the starting silicon wafers and the feasible dimensional tolerances.

Referring now to FIG. 14A, there is seen a starting silicon base wafer 162 with a requisite number of fiducial alignment marks 164 on its bottom side. Marks 162 are provided so that the wafer can be positioned reproducibly for photolithography during multiple processing steps on non-coplanar layers, including both the top surface of the starting wafer and the buried layer of the ceiling wafer. Wafers having approximate diameter of 100 or 150 mm and thickness of 350 μm or 550 μm are conveniently used, but other sizes are alternative. FIG. 14B shows the operations of a first step in which tip channel 168 having a depth of about 1 μm is formed. Resist layer 166 is photolithographically deposited to define the area of the tip channel 168, which will ultimately be part of microfabricated pipette 170. Then the wafer is plasma etched in a suitable reactor, so that material is removed from the unprotected areas, thereby forming a shallow trench of the desired shape. The resist layer then is removed. After the first step, the schematic appearance of the wafer, with its multiple tip channels, is seen in FIG. 14C.

FIG. 14D depicts the operations of a second step, in which the main through channels 172 of the microfabricated pipette 170 are formed. The area of the through channels 172 is photolithographically defined, then the uncovered areas are plasma etched to form the channels and the resist 174 is removed. In an embodiment, the through channels are etched to a depth of about 10 μm, compared to about 1 μm in the tip region formed in the previous step. The channels thus formed may have the U-shaped form depicted in FIG. 14E.

In a third step shown in FIG. 14F, a silicon-on-insulator ceiling wafer 180 is thermally bonded to the base wafer, thereby enclosing the through channels 172 of the ultimate microfabricated pipette. In one embodiment, ceiling wafer 180 is comprised of a silicon handle layer 182 (typically 300 μm thick), a buried intermediate SiO₂ layer 184 (typically 1 μm thick), and a silicon device layer 186 (typically 10 μm thick). The ceiling wafer 180 and base wafer 162 are thermally oxidized to form a thin surface SiO₂ layer on each 188, 190, and are subsequently joined by thermal fusion bonding or other methods. The surface SiO₂ layer is preferably between 0.1 μm and 10 μm thick, depending on the application. It should be sufficiently thick that the tip is mechanically stable and the pipette capacitance is less than 30 pF. After thermal bonding, the handle layer 182 is removed, preferably by mechanical grinding followed by silicon-selective etching, then the buried SiO₂ layer 184 is removed by etching to leave the device layer 186 and SiO₂ layer 188 as the ceiling enclosing the internal channels. In this embodiment, the buried SiO₂ layer 184 functions as a uniform etch-stop so that the remaining device layer 186 has a flat surface suitable for photolithography.

An alternative method employs a solid silicon wafer for the ceiling, so the buried SiO₂ layer 184 is not present. After bonding, the ceiling wafer thinned to a thickness of about 10 μm, preferably by grinding and polishing. This method avoids the expense of SOI wafers but requires the grinding and polishing step to be more precise.

In another alternative method, a solid silicon wafer is also used for the ceiling. After oxidation and bonding the ceiling wafer is thinned all the way to the surface SiO₂ layer, preferably using a combination of mechanical grinding and a final Si-selective etch. With this method, the ceiling of the pipette is transparent to visible light, which is advantageous for certain applications. Eliminating the device layer 186 also simplifies the subsequent fabrication process, particularly for geometries in which the aperture is located on the ceiling of the tip. However, in this method, the internal geometry must be designed so that the thin ceiling oxide layer is supported throughout, as it does not have the reinforcement that would be provided by device layer 186.

Fourth, photolithography and etching are used to remove material from the perimeter of the microfabricated pipettes, as shown in the operations of FIG. 14G. The area of the perimeter 204 is first defined photolithographically by deposition of resist 202. Then etching (preferably a combination of deep reactive ion etching for silicon removal and reactive ion etching for oxide removal) is used to remove the device layer and oxide layers of the ceiling wafer and the remaining thickness of the base wafer from the perimeter area, creating free perimeter 204, which extends through the full thickness of the assembly. After these operations, multiple microfabricated pipettes remain attached to the base wafer by only a breakaway tab 206, as seen in FIG. 14H.

Fifth, the tip area is released from each microfabricated pipette tip by a Si-selective KOH wet etch or other Si selective etch such as an unswitched deep reactive ion etch, as depicted in greater detail in FIG. 13 and as described above.

Finally, each tip is optionally coated with a suitable material. In a preferred implementation, the coating is a phosphosilicate glass, which is preferably heated to allow it to reflow. It is believed that the reflowing improves the surface smoothness of the glass coating, thereby improving the quality of the gigaseal formed during patching. The coating is further believed to improve electrical measurements by reducing the capacitance of the probe.

The resulting microfabricated pipette beneficially has a back portion that is sufficiently robust to be mounted in a micromanipulator, while having a slender neck and tip region that does not obscure the visual field when it is positioned as a patch-clamp seal is being formed. In addition, the microfabricated pipette has low capacitance and low source resistance, permitting electrical measurements with a low RC time constant. The relatively small diffusion distance from the tip to the inflow-outflow junction in preferred implementations of the pipette permits rapid dialysis.

The small size and reproducible construction of preferred implementations of the pipette promotes a higher rate of success in patching cells and, in some embodiments, allows a larger number of cells to be patched simultaneously and for the pipette to be incorporated into an automated system. The production cost of the pipettes is typically lower than for conventional glass pipettes. In contrast to conventional planar patch clamp technology, the present patch-clamp pipette can be employed on bulk tissue, without the requirement of dispersing individual cells in a bath. For many physiological functions, cells in bulk tissue act in concert and exhibit strikingly different behavior than the same cells taken in isolation. Thus, the present pipette and fabrication permit the patch-clamp technique to be improved in certain research areas where this was not possible before.

Optionally, the present method further includes the formation of an internal conductive structure, such as that including the conductive pads depicted in FIGS. 7-9 and an internal conductive trace. As noted above, it is beneficial for electrical measurement applications of the present pipette for the conductive path to include high-conductance portions extending as close as possible to the patched cell, as afforded by certain of the embodiments depicted. The formation of conductive paths and an associated conductive pad along the length of the pipette can be carried out by any convenient means, including those used in the formation of integrated circuits. The path and conductive pads can be located on either the bottom or ceiling portions in embodiments formed by joining the two workpieces. Preferably, the path also includes one or more vias through the pipette walls, permitting a connecting wire to be bonded to the internal conductor using techniques such as ultrasonic bonding.

In addition to functional measurement advantages, preferred embodiments having an integrated conductor system have several practical advantages. The interface between the amplifier and pipette is simplified substantially: instead of requiring a wire to be aligned and inserted into the fluid-filled back end of the pipette, the amplifier can be connected to the pipette by well-understood and widely used existing mechanical and electrical connector technologies implemented in the manipulator in which the pipette is to be secured. Such a pipette can be designed to be easily mounted and removed, either manually or by an automated system, increasing the throughput and ease of use of the patching system. The electrical connection will also have a higher degree of reliability, improving the overall reliability of recording and throughput of the system.

Similar techniques can also be used to form the electro-osmotic pump structure depicted in FIGS. 10-12. and the valves depicted in FIGS. 6, 8, and 11. In addition to the functional advantages of controlling flow within the pipette itself, such a design offers several practical advantages as well. With internal pumping and valving, the external pressure control valves and associated apparatus currently needed to control flow within the pipette, which are complex, custom-built and require constant maintenance and attention, can be eliminated and replaced and operated by electrical connections to the pump and valve circuitry. This simplifies the interface between the manipulator and pipette, eliminating the need for an external pressure control system. The flows within pipettes of a given geometry can also be characterized and calibrated during manufacture with great accuracy, eliminating the need for the experimenter to do this on a pipette-by-pipette basis. This improves the accuracy and confidence with which flows within the pipette can be controlled by the end-user.

Having thus described the invention in rather full detail, it will be understood that such detail need not be strictly adhered to, but that additional changes and modifications may suggest themselves to one skilled in the art. It is to be understood that the present system and process may be implemented in various ways, using different equipment and carrying out the steps described herein in different orders. For example, other fabrication techniques, such as electron beam lithography, can be used to carry out the formation of the pipette features instead of conventional photolithography. All of these changes and modifications are to be understood as falling within the scope of the invention as defined by the subjoined claims.

What is claimed is:

1. A microfabricated pipette, comprising:
a body section having top, bottom, and side walls, and a tip section extending from said body section,
a through internal passage extending from a back aperture proximate a back end of said body section to a patch aperture proximate a patch end of said pipette tip, said internal passage including an internal cavity in said body section in fluidic communication with an internal tip channel terminating at said patch aperture,
said pipette being configured and dimensioned to form a patch clamp seal with a cell at said patch aperture.

2. A microfabricated pipette as recited by claim 1, having a pipette capacitance less than about 30 pF.

3. A microfabricated pipette as recited by claim 1, wherein an electrical resistance “R” between said patch aperture and a pipette capacitance “C” are such that an RC time constant is less than about 10 ms.

4. A microfabricated pipette as recited by claim 1, wherein said patch aperture has a diameter ranging from about 0.1 μm to about 5 μm.

5. A microfabricated pipette as recited by claim 4, wherein said patch aperture has a diameter ranging from about 1.0 μm to about 1.6 μm.

6. A microfabricated pipette as recited by claim 1, wherein said patch aperture is approximately circular in shape.

7. A microfabricated pipette as recited by claim 1, wherein said patch aperture is approximately square in shape.

8. A microfabricated pipette as recited by claim 1, wherein said tip is coated with a tip coating material.

9. A microfabricated pipette as recited by claim 8, wherein said tip coating material comprises a hydrophobic material.

10. A microfabricated pipette as recited by claim 8, wherein said tip coating material comprises phosphosilicate glass.

11. A microfabricated pipette as recited by claim 8, wherein said tip coating material has been reflowed.

12. A microfabricated pipette as recited by claim 1, wherein said interior channel has cross sectional dimensions ranging from about from 1×1 μm to 200×200 μm.

13. A microfabricated pipette as recited by claim 1, further comprising a tapered neck section interposed between said body section and said tip section, said internal passage extending through said neck section.

14. A microfabricated pipette as recited by claim 13, wherein said neck connecting said body section and said tip section is at most about 1 mm long.

15. A microfabricated pipette as recited by claim 1, wherein said internal cavity and said internal tip channel are formed in a lower portion of said pipette and enclosed by a ceiling portion of said pipette bonded to said lower portion, and said lower portion and said ceiling portion both consist essentially of silicon having an insulating layer coating.

16. A microfabricated pipette as recited by claim 15, wherein said insulating coating consists essentially of a silicon oxide coating.

17. A microfabricated pipette as recited by claim 15, wherein said insulating coating consists essentially of a silicon nitride coating.

18. A microfabricated pipette as recited by claim 15, wherein said ceiling portion consists essentially of silicon oxide.

19. A microfabricated pipette as recited by claim 15, wherein said ceiling portion has a thickness ranging from about 0.1 μm to about 10 μm.

20. A microfabricated pipette as recited by claim 1, wherein said internal channel comprises a microfluidic manifold having a plurality of apertures proximate said back end.

21. A microfabricated pipette as recited by claim 20, wherein said microfluidic manifold comprises at least one inflow channel and one outflow channel, each said channel terminating in one of said apertures proximate said back end.

22. A microfabricated pipette as recited by claim 20, wherein said internal channel is U-shaped and connected at its bend to said tip channel.

23. A microfabricated pipette as recited by claim 21, further comprising at least one valve interposed between said tip aperture and one of said inflow and outflow channels.

24. A microfabricated pipette as recited by claim 23, wherein said valve comprises a resistive element configured to be heated to form a bubble.

25. A microfabricated pipette as recited by claim 23, wherein said valve comprises a thermally sensitive polymer gate configured to be heated to swell to impede flow.

26. A microfabricated pipette as recited by claim 20, wherein said microfluidic manifold has a plurality of inflow channels.

27. A microfabricated pipette as recited by claim 26, wherein each of said plural inflow channels includes a valve.

28. A microfabricated pipette as recited by claim 26, wherein each of said plural inflow channels includes a pump.

29. A microfabricated pipette as recited by claim 1, further comprising an electro-osmotic pump situated within said internal channel.

30. A microfabricated pipette as recited by claim 1, further comprising a conductive element extending along said internal channel and terminating at a conductive pad near said patch aperture.

31. A microfabricated pipette as recited by claim 30, wherein said conductive pad has a series resistance of at most 100 MΩ.

32. A microfabricated pipette as recited by claim 31, wherein said conductive pad has a series resistance of at most about 2 MΩ.

33. A microfabricated pipette as recited by claim 30, wherein said conductive pad comprises a coating to lower an electrical impedance of an interface between said pad and fluid contained in said pipette.

34. A microfabricated pipette as recited by claim 30, wherein said coating of said conductive pad comprises electroplated platinum black.

35. A microfabricated pipette as recited by claim 30, wherein said coating of said conductive pad comprises titanium nitride.

36. A microfabricated pipette as recited by claim 30, wherein said coating of said conductive pad comprises carbon nanotubes.

37. A microfabricated pipette as recited by claim 30, wherein said conductive element consists essentially of at least one metal selected from the group consisting of W, Ti, Ir, and alloys thereof.

38. A microfabricated pipette as recited by claim 30, wherein said conductive element consists essentially of a doped polysilicon.

39. A microfabricated pipette as recited by claim 1, wherein said tip further comprises a second patch aperture terminating a second internal tip channel in fluidic communication with a second internal cavity situated in said body section and terminating in a second back aperture.

40. A method for microfabricating a pipette having top, bottom, and side walls and a pipette tip, and a through internal passage extending from a back aperture proximate a back end through an internal tip channel to a patch aperture in a patch end of said pipette tip, comprising the steps of:
a) providing a base wafer having a top surface and a bottom surface and a ceiling wafer having a top surface and a bottom surface;
b) removing material from a portion of said top surface of said base wafer to form therein said internal passage comprising an internal cavity in fluidic communication with an internal channel;
c) coating said bottom surface of said ceiling wafer with an insulating layer and said top surface of said base wafer with an insulating layer;
d) bonding said bottom surface of said ceiling wafer to said top surface of said base wafer to enclose said internal passage;
e) thinning said ceiling wafer by removing material from substantially all of said top surface;
f) defining side walls of said pipette by removing material of said base wafer and said ceiling wafer surrounding said internal tip channel; and
g) releasing said pipette tip by removing material of said base wafer and said ceiling wafer surrounding said internal tip channel, and
whereby said pipette is configured and dimensioned to form a patch clamp seal with a cell at said patch aperture.

41. A method as recited by claim 40, wherein said base wafer and said ceiling wafer consist essentially of silicon

42. A method as recited by claim 40, wherein said pipette comprises a body section, a neck section, and a tip section, and said neck section and said tip section extend from said body section.

43. A method as recited by claim 40, further comprising the step of:
h) coating said tip with a tip coating material.

44. A method as recited by claim 43, wherein said tip coating material comprises a hydrophobic material.

45. A method as recited by claim 43, wherein said tip coating material is deposited by a low pressure chemical vapor deposition process.

46. A method as recited by claim 45 wherein said tip coating material is a phosphosilicate glass.

47. A method as recited by claim 46, further comprising the step of:
i) reflowing said tip coating material by heating.

48. A microfabricated pipette as recited by claim 1, wherein said body section and said tip section are formed separately and thereafter joined.

49. A microfabricated pipette as recited by claim 15, wherein at least one of said lower portion and said ceiling portion is fabricated using an SOI wafer.

50. A method as recited by claim 41, wherein at least one of said base wafer and said ceiling wafer is an SOI wafer.

51. A method as recited by claim 41, wherein said thinning comprises removal of substantially all of said ceiling portion above said insulating layer.

52. A method as recited by claim 40, further comprising the step of:
j) forming a conductive path within said pipette.

53. A method as recited by claim 40, further comprising the step of:
k) forming an electro-osmotic pump within said pipette.

54. A method of measuring electrical activity of a living cell, comprising the steps of:
a) providing a microfabricated pipette as recited by claim 1;
b) establishing a patch-clamp seal between said pipette and said cell; and
c) measuring an electrical activity of said cell.

55. A method as recited by claim 54, further comprising the steps of:
d) mounting said pipette on a manipulator and establishing a direct electrical connection to said pipette; and
e) dialyzing said cell using said internal perfusion system.
